(19) United States
(12) Patent Application Publication
(10) Pub. No.: US 2026/0293566 A1
(43) Pub. Date: Sep. 24, 2026

(54) WAFER PROCESSING METHOD

(71) Applicant: DISCO CORPORATION, Tokyo (JP)

(72) Inventors: Makiko Ohmae, Tokyo (JP); Shigenori Harada, Tokyo (JP)

(21) Appl. No.: 19/552,552

(22) Filed: Feb. 27, 2026

(30) Foreign Application Priority Data
Mar. 19, 2025 (JP) 2025-045488

(51) Int. Cl. H10P 58/00; H10P 70/00

(52) U.S. Cl. CPC H10P 58/22; H10P 70/30

(57) ABSTRACT

The present disclosure provides a wafer processing method with which swarf do not remain in the division groove. The wafer processing method includes: forming half-cut grooves on a front face of the wafer correspondingly with chips to be formed; disposing a protective member on a front face of the wafer on which the half-cut grooves are formed; dividing the wafer into individual chips by grinding a back surface side of the wafer to expose the half-cut grooves on the back surface side of the wafer so as to form division grooves; and cleaning the wafer on which the division grooves are formed. In the cleaning, cleaning water, of which resistivity has been lowered by supplying gas, is infiltrated into the division grooves, so as to remove swarf from the division grooves.

### BACKGROUND

### 1. Technical Field

The present disclosure relates to a wafer processing method of dividing a wafer into individual chips.

### 2. Description of the Related Art

A wafer, on the surface of which a plurality of devices, e.g. IC or LSI, are formed, and which is demarcated by division lines, is divided into individual device chips by a cutting apparatus, a plasma apparatus, or the like, and each of the divided device chips is used for electronic devices such as a smartphone and a personal computer.

A cutting apparatus includes: a holding unit which holds a wafer; a cutting unit which rotatably includes a cutting blade for cutting the wafer held by the holding unit; a feeding unit which relatively feeds the holding unit and the cutting unit for processing; and an alignment unit which images the wafer held by the holding unit and detects division lines to cut. The cutting apparatus can divide a wafer into individual device chips at high precision (e.g. see JP 2023-078942 A).

The present applicant also proposed a technique of forming half-cut grooves on division lines by using a cutting blade or a laser beam, then expose the half-cut grooves on a back surface side of the wafer by grinding the back surface side of the wafer, and subsequently divide the wafer into individual chips (see JP 2008-226982 A).

### SUMMARY

However in a case where division grooves are formed by grinding the back surface side of the wafer and exposing the half-cut grooves on the back surface side, swarf that are generated when the wafer is divided into individual device chips may remain in the device grooves. In this case, it is difficult to sufficiently remove the swarf remaining in the division grooves, even if cleaning is performed using two fluids by injecting cleaning water with high pressure air. If the swarf remain in the division grooves, the swarf remaining in the division grooves may fall off when the device chip is picked up and bonded to a circuit board. This drops the quality of an electronic component.

Another problem of grinding the back surface side of the wafer first and then polishing the back surface side of the wafer to enhance flexural strength by removing grinding marks, is that the swarf generated by polishing enter the division grooves, and removal of the swarf becomes even more difficult. This problem is conspicuous especially in the case of forming half-cut grooves by plasma etching of which groove width is narrow.

An object of the present disclosure is to provide a wafer processing method with which swarf do not remain in the division grooves.

The present disclosure provides a following wafer processing method to solve the above mentioned problem, that is, a wafer processing method for dividing a wafer into individual chips, the method including: forming half-cut grooves on a front face of the wafer correspondingly with chips to be formed; disposing a protective member on the front face of the wafer on which the half-cut grooves are formed;

dividing the wafer into individual chips by grinding a back surface side of the wafer to expose the half-cut grooves on the back surface side of the wafer so as to form a division groove; and cleaning the wafer on which the division grooves are formed. In the cleaning, cleaning water, of which resistivity has been lowered by supplying gas, is infiltered into the division grooves, so as to remove swarf from the division grooves.

It is preferable that the grinding of the back surface side of the wafer in the dividing includes a case in which the back surface side of the wafer is ground using a grinding wheel, which includes annularly arranged grinding stones, and then the ground back surface side of the wafer is polished using a polishing pad so as to remove grinding marks.

It is preferable that the half-cut groove forming includes a case in which the half-cut grooves are formed using a cutting blade, a case in which the half-cut grooves are formed using a laser beam, and a case in which the half-cut grooves are formed by plasma etching, and a width of the division groove is 20 μm or less.

It is preferable that the cleaning is executed with a cleaning apparatus including: a spinner table which rotatably holds a wafer; and a cleaning water injection unit which injects cleaning water to the wafer held by the spinner table. The cleaning water injection unit includes: a resistivity lowering portion which supplies gas to the cleaning water to lower the resistivity; a pressurizing portion which pressurizes the cleaning water; and a nozzle portion which injects the pressurized cleaning water to the wafer.

It is preferable that the pressurizing portion pressurizes the clean water with air. The resistivity of the cleaning water is preferably 2MΩ • cm or less. The resistivity of the cleaning water is also preferably 0.8MΩ • cm or less. The gas that lowers the resistivity of the cleaning water preferably contains CO₂, N₂ or He.

The wafer processing method of the present disclosure is a wafer processing method for dividing a wafer into individual chips, including: forming half-cut grooves on a front face of the wafer so as to correspond with chips to be formed; disposing a protective member on the front face of the wafer on which the half-cut grooves are formed; dividing the wafer into individual chips by grinding a back surface side of the wafer to expose the half-cut grooves on the back surface side of the wafer so as to form division grooves; and cleaning the wafer on which the division grooves are formed. In the cleaning, cleaning water, of which resistivity has been lowered by supplying gas, is infiltered into the division grooves, so as to remove swarf from the division grooves. Therefore swarf do not remain in the division grooves.

### BRIEF DESCRIPTION OF THE DRAWINGS

FIG. 1 is a perspective view of a wafer;

FIG. 2A is a schematic diagram depicting a state of forming half-cut grooves using a cutting blade, and FIG. 2B is a partial cross-sectional view of the wafer on which the half-cut grooves are formed;

FIG. 3A is a schematic diagram depicting a state of forming half-cut grooves using a laser beam, and FIG. 3B is a partial cross-sectional view of a wafer on which a modified layer is formed as half-cut grooves;

FIG. 4 is a schematic diagram depicting a state of forming half-cut grooves by plasma etching;

FIG. 5 is a schematic diagram depicting disposing a protective member;

FIG. 6 is a schematic diagram depicting a state of grinding a back surface side of a wafer in dividing thereof;

FIG. 7 is a schematic diagram depicting a state of polishing the back surface side of the wafer in the dividing;

FIG. 8 is a perspective view of a cleaning apparatus;

FIG. 9 is a schematic diagram depicting a state of performing cleaning a wafer using the cleaning apparatus illustrated in FIG. 8; and

FIG. 10 is a perspective view of a wafer transferred from a protective tape to a dicing tape after being divided into individual chips.

### DESCRIPTION OF THE PREFERRED EMBODIMENTS

Embodiments of the wafer processing method according to the present disclosure will be described with reference to the drawings.

### Wafer 2

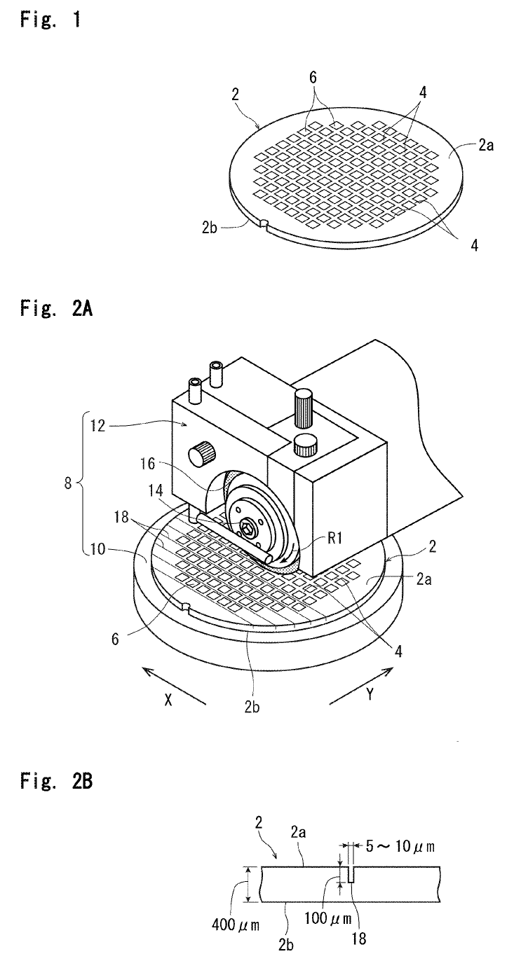

In FIG. 1, a disk-shaped wafer 2, to be processed by the method according to the present disclosure, is illustrated. The wafer 2 is formed of an appropriate semiconductor material, e.g. silicon. Dimensions of the wafer 2 are: 300 mm diameter and about a 400 μm thickness, for example. A front face 2a of the wafer 2 is demarcated to a plurality of rectangular regions by latticed division lines 4. On each of the plurality of rectangular regions, such a device 6 as an IC and LSI is formed.

### Half-cut Groove Forming

In the present embodiment, forming half-cut grooves on a front face 2a of the wafer 2, so as to correspond with chips to be formed, is performed first.

### Dicing Apparatus 8

The half-cut groove forming is performed using a dicing apparatus 8 illustrated in FIG. 2A, for example. The dicing apparatus 8 includes a chuck table 10 which suction-holds the wafer 2, and a cutting unit 12 which cuts the wafer 2 that is suction-held by the chuck table 10.

### Chuck Table 10 of Dicing Apparatus 8

The chuck table 10 is configured such that the wafer 2 is suction-held on an upper face thereof. The chuck table 10 is configured to be rotatable around a shaft in a vertical direction, and to be movable freely in an X axis direction indicated by an arrow X in FIG. 2A.

### Cutting Unit 12 of Dicing Apparatus 8

The cutting unit 12 includes: a spindle 14 configured to be rotatable around a shaft in a Y axis direction (direction indicated by an arrow Y in FIG. 2A) which orthogonally intersects with the X axis direction; and an annular cutting blade 16 fixed at a tip of the spindle 14. An edge of the cutting blade 16 is formed of abrasive grains, e.g. diamond abrasive grains, and a bonding material, e.g. metal or resin, to have a predetermined thickness (e.g. approximately 5 to 20 μm). An XY plane determined by the X axis direction and the Y axis direction is substantially horizontal.

To perform the half-cut groove forming by using the dicing apparatus 8, the front face 2a of the wafer 2 is positioned upward and the wafer 2 is suction-held on the upper face of the chuck table 10. Then the wafer 2 is imaged from above by an imaging unit (not illustrated) of the dicing apparatus 8, and division lines 4 are aligned with the X axis direction based on the image of the wafer 2 captured by the imaging unit. Then the edge of the cutting blade 16, which is rotating at high-speed in a direction indicated by an arrow R1 in FIG. 2A, implements cut along the division line 4 for a predetermined depth (e.g. 100 μm) from the front face 2a. Here while supplying cutting water into a portion where the edge of the cutting blade 16 cuts, the chuck table 10 is fed for processing in the X axis direction. Thereby half-cut grooves 18 having a predetermined depth can be formed along the division lines 4 (see FIG. 2B). The depth of the half-cut grooves 18 is about 100 μm, and the width of each half-cut groove 18 is about 5 to 20 μm.

Then the cutting blade 16 is index-fed in the Y axis direction for the amount of distance of the division lines 4 in the Y axis direction. By repeating the formation of the half-cut groove 18 and the index-feeding alternately, half-cut grooves 18 are formed along all the division lines 4 aligned in the X axis direction.

Further, the chuck table 10 is rotated 90°, then formation of the half-cut groove 18 and the index-feeding are alternately repeated. Thereby the half-cut grooves 18 are formed along all the division lines 4 intersecting orthogonally with the division lines 4 where the half-cut grooves 18 were previously formed. In this way, the latticed half-cut grooves 18 are formed on the front face 2a of the wafer 2, along the latticed division lines 4.

### Laser Processing Apparatus 20

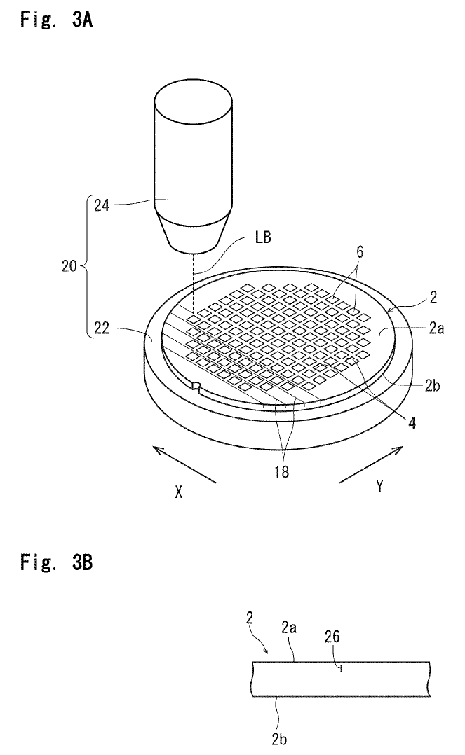

The half-cut groove forming may also be performed using a laser processing apparatus 20 illustrated in FIG. 3A. The laser processing apparatus 20 includes: a chuck table 22 which suction-holds a wafer 2; an oscillator (not illustrated) which oscillates a pulsed laser beam LB having an absorption wavelength with respect to the wafer 2; and a condenser 24 which condenses the pulsed laser beam LB oscillated by the oscillator, and applies the laser beam onto the wafer 2 which is suction-held by the chuck table 22.

To perform the half-cut groove forming by using the laser processing apparatus 20, the front face 2a of the wafer 2 is positioned upward, and the wafer 2 is suction-held on the upper face of the chuck table 22. Then the wafer 2 is imaged from above by an imaging unit (not illustrated) of the laser processing apparatus 20, and division lines 4 are aligned with the X axis direction based on the image of the wafer 2 captured by the imaging unit. Further, the laser beam LB is aimed at the division line 4 aligned with the X axis direction, and the condensing point of the laser beam LB is positioned on the front face 2a of the wafer 2. To prevent the adhesion of debris to the front face 2a of the wafer 2, it is preferable to coat the front face 2a with a protective film, e.g. water soluble resin, in advance.

Then while feeding the chuck table 22 for processing in the X axis direction, the laser beam LB having the absorption wavelength with respect to the wafer 2 is applied from the condenser 24 onto the wafer 2. Thereby ablation processing is performed on the front face 2a of the wafer 2, and the half-cut grooves 18 having a predetermined depth can be formed along the division lines 4. Then just like the case of forming half-cut grooves 18 using the dicing apparatus 8, applying the laser beam LB and the index-feeding are alternately repeated, and the latticed half-cut grooves 18 are formed on the front face 2a of the wafer 2 along the latticed division lines 4.

In the case of forming the half-cut groove using the laser processing apparatus 20, a modified layer 26 may be formed as the half-cut grooves 18 on the front face 2a side of the wafer 2, as illustrated in FIG. 3B. In the case of forming the modified layer 26 as well, the wafer 2 can be divided into individual chips because of cracks that extend from the modified layer 26 by performing the later mentioned dividing. In other words, the half-cut grooves 18 in the present description may be any grooves to be a start point of dividing the wafer 2 into individual chips by performing the dividing. In the case of forming the modified layer 26 as the half-cut grooves 18, the condensing point of the laser beam having a transmissive wavelength with respect to the wafer 2 is positioned inside the wafer 2, and the laser beam is applied to the wafer 2.

### Plasma Etching Apparatus

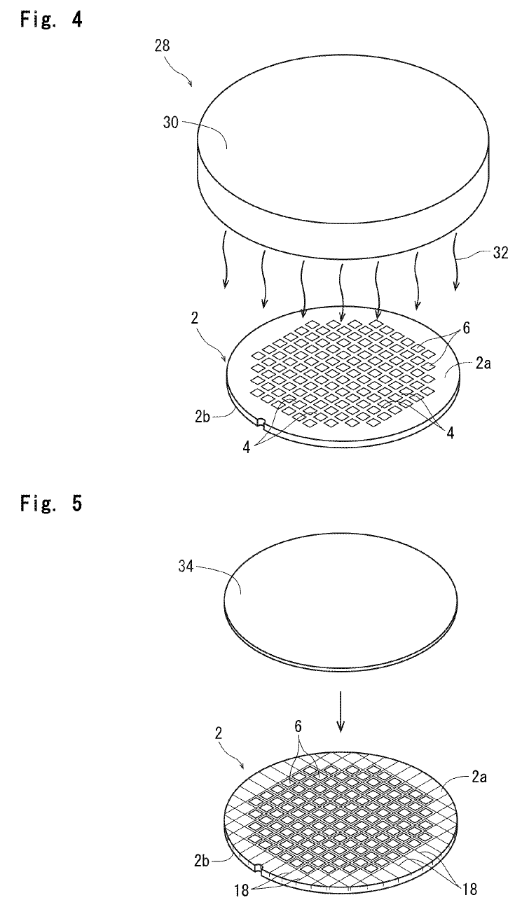

The half-cut groove forming may also be performed by using a plasma apparatus 28 illustrated in FIG. 4. The plasma apparatus 28 includes: a chamber (not illustrated) which forms a sealed space; an upper electrode and a lower electrode (neither are illustrated) which are disposed in the chamber at a distance from each other in the vertical direction; and a gas injection unit 30 which injects etching gas inside the chamber.

To form the half-cut grooves 18 using the plasma apparatus 28, a predetermined mask is formed on the front face 2a of the wafer 2 by photolithography. Then the wafer 2 is set in the chamber, positioning the front face 2a, on which the mask is formed, upward. Then etching gas (e.g. fluorine-containing gas) is supplied from the gas injection unit 30 into the chamber, and high frequency power is applied to generate plasma to the upper electrode. The plasmatic etching gas 32 is generated between the upper electrode and the lower electrode, and the plasmatic etching gas 32 is supplied to the front face 2a of the wafer 2. As a result, the latticed half-cut grooves 18 are formed on the front face 2a of the wafer 2 along the latticed division lines 4.

As described above, the half-cut groove forming may include (1) the case of forming the half-cut grooves 18 using the cutting blade 16, (2) the case of forming the half-cut grooves 18 using the laser beam LB, and (3) the case of forming the half-cut grooves 18 by plasma etching.

### Protective Member Disposing

After performing the half-cut groove forming, disposing a protective member 34 on the front face 2a of the wafer 2 on which the half-cut grooves 18 are formed, as illustrated in FIG. 5, is performed. The protective member 34 may be an adhesive tape or a thermocompression bonding tape. The thermocompression bonding tape is a type of thermoplastic synthetic resin (e.g. polyolefin resin), which softens or melts when heated to a temperature near the melting point, and becomes an adhesive. The shape of the protective member 34 may be a circle of which diameter is about the same as the diameter of the wafer 2.

### Dividing

After performing the protective member disposing, dividing the wafer into individual chips by grinding a back surface side 2b of the wafer 2 to expose the half-cut grooves 18 on the back surface side 2b of the wafer 2 so as to form the division grooves and is performed.

### Grinding Apparatus 36

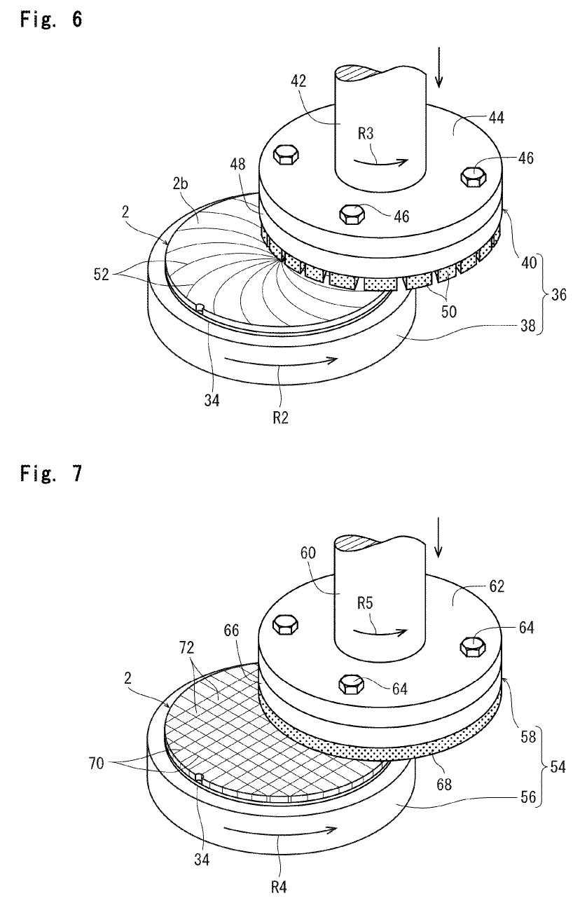

The dividing is performed using a grinding apparatus 36 illustrated in FIG. 6, for example. The grinding apparatus 36 includes: a chuck table 38 which suction-holds the wafer 2; and a grinding unit 40 which grinds the wafer 2 that is suction-held by the chuck table 38. The grinding unit 40 includes: a spindle 42 which extends in a vertical direction; and a disk-shaped wheel mount 44 which is fixed at a lower end of the spindle 42. An annular grinding wheel 48 is fastened to the lower face of the wheel mount 44 by bolts 46. On an outer periphery of the lower face of the grinding wheel 48, a plurality of annularly arranged grinding stones 50 are fixed at intervals in a circumferential direction.

To perform the dividing, the back surface side 2b of the wafer 2 is positioned upward, and the wafer 2 is suction-held on the upper face of the chuck table 38. Then the chuck table 38 is rotated at a predetermined rotation speed (e.g. 300 rpm) in a direction indicated by an arrow R2 in FIG. 6. Further, the spindle 42 is rotated at a predetermined rotation speed (e.g. 6000 rpm) in a direction indicated by an arrow R3. Then the spindle 42 is lowered so that the grinding stones 50 contact with the back surface side 2b of the wafer 2, while supplying grinding water to the portion where the grinding stones 50 contact with the back surface side 2b. Then the spindle 42 is lowered at a predetermined grinding feeding speed (e.g. 1.0 μm/s). Thereby the back surface side 2b of the wafer 2 is ground, and the wafer 2 is thinned to be a predetermined thickness.

In the dividing, the back surface side 2b of the wafer 2 may be ground by the grinding stones 50 of the grinding apparatus 36 until the half-cut grooves 18 are exposed, but in the present embodiment, the back surface side 2b of the wafer 2 is ground by the grinding apparatus 36 such that the half-cut grooves 18 are not exposed. Therefore at the point when grinding by the grinding apparatus 36 ends, the wafer 2 has not yet been divided into individual chips. FIG. 6 is a state where a plurality of arc-shaped grinding marks 52, which extend radially from the center of the wafer 2 in the diameter direction, have been generated on the back surface side 2b of the wafer 2 by grinding using the grinding apparatus 36.

In the dividing of the present embodiment, the back surface side 2b of the wafer 2 is polished after performing the grinding using the grinding apparatus 36. Thereby the half-cut grooves 18 are exposed on the back surface side 2b of the wafer 2, and the division grooves are formed. The wafer 2 is then divided into individual chips by the division grooves.

### Polishing Apparatus 54

The back surface side 2b of the wafer 2 is polished using a polishing apparatus 54 illustrated in FIG. 7, for example. The polishing apparatus 54 includes: a chuck table 56 which suction-holds the wafer 2; and a polishing unit 58 which polishes the wafer 2 that is suction-held by the chuck table 56. The polishing unit 58 includes: a spindle 60 which extends in a vertical direction; and a disk-shaped mount 62 which is fixed at a lower end of the spindle 60. A disk-shaped base 66 is fastened to the lower face of the mount 62 by bolts 64. A disk-shaped polishing pad 68 is fixed to the lower face of the base 66. The polishing pad 68 may be formed of a synthetic resin, e.g. polyurethane, containing abrasion grains, or non-woven fabric, e.g. felt, containing abrasion grains.

To polish the back surface side 2b of the wafer 2 in the dividing, the back surface side 2b of the wafer 2 is positioned upward, and the wafer 2 is suction-held on the upper face of the chuck table 56. Then the chuck table 56 is rotated at a predetermined rotation speed (e.g. 500 rpm) in a direction indicated by an arrow R4 in FIG. 7. Further, the spindle 60 is rotated at a predetermined rotation speed (e.g. 500 rpm) in a direction indicated by an arrow R5. Then the spindle 60 is lowered so that the lower face of the polishing pad 68 is pressed onto the back surface side 2b of the wafer 2, and the back surface side 2b of the wafer 2 is polished. Thereby the half-cut grooves 18 are exposed on the back surface side 2b of the wafer 2, and the division grooves 70 are formed so that the wafer 2 is divided into individual device chips 72. The grinding marks 52 are also removed from the back surface side 2b of the wafer 2. The width of each division groove 70 is the same as the width of each half-cut groove 10, and is about 5 to 20 μm.

In the grinding using the grinding apparatus 36 according to the present embodiment, the wafer 2 is not divided into device chips 72, but after performing grinding using the grinding apparatus 36, polishing is performed using the polishing apparatus 54, whereby the wafer 2 is divided into the device chips 72. In other words, in “dividing the wafer 2 into individual chips by grinding the back surface side 2b of the wafer 2 to expose the half-cut grooves 18 on the back surface side 2b of the wafer 2 so as to form the division grooves 70”, “grinding the back surface side 2b of the wafer 2” includes a case of grinding the back surface side 2b of the wafer 2 using the grinding wheel 48, which includes the annularly arranged grinding stones 50, and then polishing the ground back surface side 2b of the wafer 2 using the polishing pad 68 so as to remove grinding marks 52. However in the dividing, the wafer 2 may be divided into the device chips 72 by grinding using the grinding apparatus 36, omitting the polishing using the polishing apparatus 54, or polishing using the polishing apparatus 54 may be performed after dividing the wafer 2 into the device chips 72 by grinding using the grinding apparatus 36.

The polishing of the back surface side 2b of the wafer 2 may be wet polishing, which is performed while supplying polishing solution, e.g. slurry or pure water, into a portion between the back surface side 2b of the wafer 2 and the polishing pad 68, or may be dry polishing, which is performed without supplying the polishing solution into the portion between the back surface side 2b of the wafer 2 and the polishing pad 68. In the dry polishing, however, swarf tend to remain in the division grooves 70 more easily compared with the wet polishing.

Furthermore, when the modified layer 26 is formed as the half-cut grooves 18, the pressing force applied during grinding or polishing of the wafer 2 causes cracks to extend from the modified layer 26 in the thickness direction of the wafer 2, forming the division grooves 70. This divides the wafer 2 into individual device chips 72.

### Cleaning

After performing the dividing, cleaning the wafer 2 on which the division grooves 70 are formed, is performed.

### Cleaning Apparatus 74

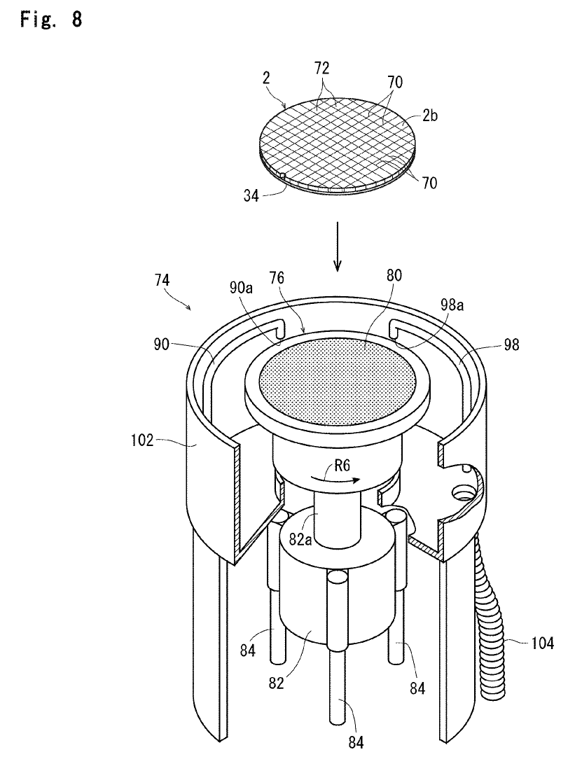

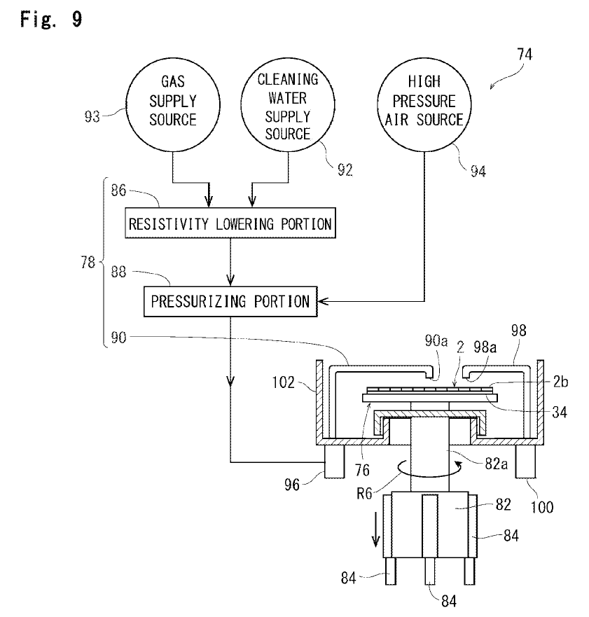

The cleaning is performed using a cleaning apparatus 74 illustrated in FIGS. 8 and 9, for example. The cleaning apparatus 74 includes: a spinner table 76 which rotatably holds a wafer 2; and a cleaning water injection unit 78 (see FIG. 9) which injects cleaning water onto the wafer 2 held by the spinner table 76.

### Spinner Table 76 of Cleaning Apparatus 74

As illustrated in FIG. 8, a circular suction chuck 80 is disposed on an upper end portion of the spinner table 76. The suction chuck 80 is formed of a porous member, e.g. porous ceramics, and is connected to a suction pump (not illustrated). In the spinner table 76, the suction pump generates a suction force on the upper face of the suction chuck 80, so as to suction-hold the wafer 2 placed on the upper face of the suction chuck 80.

A rotation shaft 82a of a motor 82 is connected to the center of the spinner table 76 to rotate the spinner table 76. The motor 82 rotates the spinner table 76 around the shaft in the vertical direction. On an outer peripheral surface of the motor 82, an elevating unit 84, which is configured by an actuator, e.g. air cylinder, is installed. The elevating unit 84 raises and lowers the spinner table 76 between a raised position (position illustrated in FIG. 8) where the wafer 2 is attached/detached, and a lower position (position illustrated in FIG. 9) where the wafer 2 is cleaned.

### Cleaning Water Injection Unit 78 of Cleaning Apparatus 74

As illustrated in FIG. 9, the cleaning water injection unit 78 includes: a resistivity lowering portion 86 which supplies gas to the cleaning water to lower the resistivity; a pressurizing portion 88 which pressurizes the cleaning water; and a nozzle portion 90 which injects the pressurized cleaning onto the wafer 2.

### Resistivity Lowering Portion 86 of Cleaning Water Injection Unit 78

In the resistivity lowering portion 86, the cleaning water(e.g. pure water), supplied from a cleaning water supply source 92, and gas (e.g. CO₂, N₂ or He), supplied from a gas supply source 93, are mixed. The resistivity of the cleaning water in the resistivity lowering portion 86 is preferably 2 MΩ • cm or less, and is more preferably 0.8 MΩ • cm or less. When the cleaning water and CO₂ are mixed in the resistivity lowering portion 86, the resistivity of the cleaning water could be lowered to about 0.05 MΩ • cm. When the cleaning water and N₂ are mixed, the resistivity of the cleaning water could be lowered to about 0.24 MΩ • cm. When the cleaning water and He are mixed, the resistivity of the cleaning water could be lowered to about 0.5 MΩ • cm.

### Pressurizing Portion 88 of Cleaning Water Injection Unit 78

The pressurizing portion 88 pressurizes the cleaning water, in which bubbles are generated, by high pressure air. The pressurizing portion 88 is disposed on the downstream side of the resistivity lowering portion 86. The high pressure air (e.g. 0.4 MPa air) is supplied from a high pressure air source 94 to the pressurizing portion 88.

### Nozzle Portion 90 of Cleaning Water Injection Unit 78

The cleaning water pressurized by the pressurizing portion 88 is supplied to the nozzle portion 90, and the cleaning water and air (two fluids) are injected from an injection port 90a of the nozzle portion 90 toward the wafer 2 held by the spinner table 76. As illustrated in FIGS. 8 and 9, the injection port 90a of the nozzle portion 90 is disposed above the wafer 2 held by the spinner table 76. A turning motor 96 (see FIG. 9) is installed in the nozzle portion 90. By being turned by the turning motor 96, the nozzle portion 90 is positioned at a standby position (position illustrated in FIG. 8) where the injection port 90a is moved away from the portion directly above the spinner table 76, and an injection position (position illustrated in FIG. 9) where the injection port 90a is positioned above the center portion of the spinner table 76.

As illustrated in FIGS. 8 and 9, the cleaning apparatus 74 includes: an air nozzle 98 which injects dry air onto the wafer 2 held by the spinner table 76; a turning motor 100 (see FIG. 9) which turns the air nozzle 98; a drain pan 102 which collects the cleaning water injected from the nozzle portion 90; and a drain hose 104 (see FIG. 8) which drains the cleaning water collected by the drain pan 102. By being turned by the turning motor 100, the air nozzle 98 is positioned at the standby position (position illustrated in FIG. 8) where an injection port 98a is moved away from the portion directly above the spinner table 76, and an injection position where the injection port 98a is positioned above the center portion of the spinner table 76.

In the cleaning, the back surface side 2b of the wafer 2 is positioned upward and the wafer 2 is suction-held by the spinner table 76. Here the spinner table 76 is positioned at the raised position illustrated in FIG. 8, and the nozzle portion 90 and the air nozzle 98 are positioned at the standby position illustrated in FIG. 8 in advance.

Once the wafer 2 is suction-held by the spinner table 76, the cleaning water is injected toward the wafer 2 to clean the wafer 2. Here the spinner table 76 is positioned at the lowered position first. Then the nozzle portion 90 is turned to the injection position, and the injection port 90a is positioned above the center portion of the wafer 2, as illustrated in FIG. 9. Then while rotating the spinner table 76 at a predetermined rotation speed (e.g. 400 rpm) in the direction indicated by an arrow R6 in FIG. 9, a predetermined amount (e.g. 0.2 L/min) of cleaning water is injected from the injection port 90a of the nozzle portion 90 so as to clean the wafer 2.

To clean the wafer 2, the cleaning water, of which resistivity has been lowered, and air (two fluids) are injected from the injection port 90a of the nozzle portion 90 toward the wafer 2 held by the spinner table 76. In other words, the clean water is supplied from the cleaning water supply source 92 to the resistivity lowering portion 86, and the gas, e.g. CO₂, is supplied from the gas supply source 93 at the same time, so as to lower the resistivity of the cleaning water in the resistivity lowering portion 86. Then in the pressurizing portion 88, the cleaning water, of which resistivity has been lowered, is pressurized by the high pressure air supplied from the high pressure air source 94, whereby the cleaning water of which resistivity has been lowered and the air are injected from the injection port 90a of the nozzle portion 90.

Then the static electricity of the wafer 2 is removed by the cleaning water of which resistivity has been lowered. This decreases the adsorption force between the swarf and the wafer 2 caused by static electricity, hence the swarf float above the division grooves 70 due to the cleaning water infiltrated into the division grooves 70, and the floating swarf are removed from the wafer 2 by the cleaning water and the air injected from the nozzle portion 90. Thus swarf do not remain in the division grooves 70 according to the present embodiment. Hence the problem of dropping in the quality of the electronic component when the device chips 72 are picked up and bonded to the circuit board, the swarf that remain in the division grooves 70 falls off, can be solved.

When the wafer 2 is cleaned, the dry air is injected toward the wafer 2 to dry the wafer 2. Here the nozzle portion 90 is turned to the standby position. The air nozzle 98 is turned to the injection position, and the injection port 98a is positioned above the center portion of the wafer 2. Then while rotating the spinner table 76 at a predetermined rotation speed (e.g. 2000 rpm) in the direction indicated by an arrow R6, the dry air is injected from the injection port 98a of the air nozzle 98 so as to dry the wafer 2.

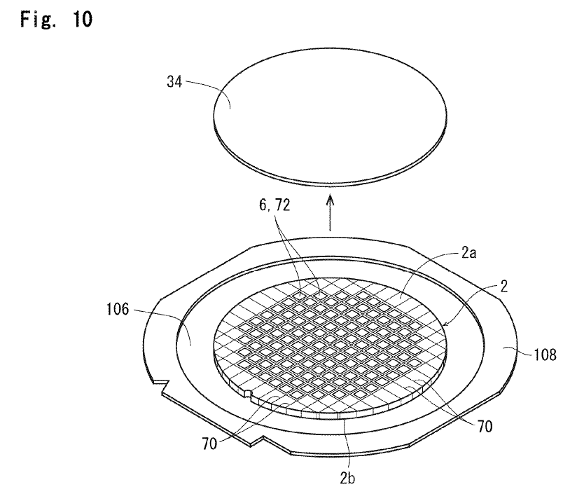

As illustrated in FIG. 10, after transferring the wafer 2, on which the division grooves 70 are formed, from the protective member 34 to a dicing tape 106, the cleaning may be performed again. In other words, after the cleaning is performed, the back surface side 2b of the wafer 2 is attached to the circular dicing tape 106, of which periphery is fixed to an annular frame 108, then the protective member 34 is peeled off from the front face 2a of the wafer 2. Then the cleaning may be performed again. Further, after performing the cleaning and transferring the wafer 2 from the protective member 34 to the dicing tape 106, radial tension may be applied to the dicing tape 106 using a known expanding apparatus (not illustrated), to widen the intervals of the division grooves 70. Then the cleaning may be performed again. Thereby inside of the division grooves 70 can be cleaned even more effectively. Particularly in the case of forming the modified layer 26 as the half-cut grooves 18 and dividing the wafer 2 into individual device chips 72, it is preferable to widen the intervals of the division grooves 70 first, and then perform the cleaning.

As described above, in the wafer processing method of the present embodiment, the cleaning water, of which resistivity has been lowered, and the air (two fluids) are injected toward the wafer 2 in the cleaning, hence static electricity of the wafer 2 is removed, and the adsorption force between the swarf and the wafer 2, caused by static electricity, drops. As a result, the swarf float above the division groove 70 due to the cleaning water infiltrated into the division grooves 70, and the floating swarf are removed from the wafer 2 by the cleaning water and the air injected from the nozzle portion 90. Therefore according to the present embodiment, the swarf do not remain in the division grooves 70, and the problem of dropping in the quality of the electronic component when the device chip is picked up and bonded to a circuit board, the swarf that remain in the division grooves 70 falls off, can be solved.

### REFERENCE SIGNS LIST

2 Wafer

2a Front face of wafer

2b Back surface side of wafer

4 Division line

6 Device

16 Cutting blade

18 Half-cut groove

34 Protective member

48 Grinding wheel

50 Grinding stone

52 Grinding mark

68 Polishing pad

70 Division groove

72 Device chip

74 Cleaning apparatus

76 Spinner table

78 Cleaning water injection unit

86 Resistivity lowering portion

88 Pressurizing portion

90 Nozzle portion

90a Injection port of nozzle portion

What is claimed is:

1. A wafer processing method for dividing a wafer into individual chips, the method comprising:
forming half-cut grooves on a front face of the wafer correspondingly with chips to be formed;
disposing a protective member on the front face of the wafer on which the half-cut grooves are formed;
dividing the wafer into individual chips by grinding a back surface side of the wafer to expose the half-cut grooves on the back surface side of the wafer so as to form division grooves; and
cleaning the wafer on which the division grooves are formed, wherein
in the cleaning, cleaning water, of which resistivity has been lowered by supplying gas, is infiltered into the division grooves, so as to remove swarf from the division grooves.

2. The wafer processing method of claim 1, wherein
the grinding of the back surface side of the wafer in the dividing includes a case in which the back surface side of the wafer is ground using a grinding wheel, which includes annularly arranged grinding stones, and then the ground back surface side of the wafer is polished using a polishing pad so as to remove grinding marks.

3. The wafer processing method of claim 1, wherein
the half-cut groove forming includes a case in which the half-cut grooves are formed using a cutting blade, a case in which the half-cut grooves are formed using a laser beam, and a case in which the half-cut grooves are formed by plasma etching, and
a width of the division groove is 20 μm or less.

4. The wafer processing method of claim 1, wherein
the cleaning is executed with a cleaning apparatus including: a spinner table which rotatably holds a wafer; and a cleaning water injection unit which injects cleaning water to the wafer held by the spinner table, wherein
the cleaning water injection unit includes: a resistivity lowering portion which supplies gas to the cleaning water to lower the resistivity; a pressurizing portion which pressurizes the cleaning water; and a nozzle portion which injects the pressurized cleaning water to the wafer.

5. The wafer processing method of claim 4, wherein
the pressurizing portion pressurizes the cleaning water with air.

6. The wafer processing method of claim 1, wherein
the resistivity of the cleaning water is 2 MΩ • cm or less.

7. The wafer processing method of claim 1, wherein
the resistivity of the cleaning water is 0.8 MΩ • cm or less.

8. The wafer processing method of claim 1, wherein
the gas that lowers the resistivity of the cleaning water contains CO₂ N₂8 or He.
